(19) United States
(12) Patent Application Publication
(10) Pub. No.: US 2026/0101822 A1
(43) Pub. Date: Apr. 9, 2026

(54) SEMICONDUCTOR PACKAGE

(71) Applicant: Samsung Electronics Co., Ltd., Suwon-si (KR)

(72) Inventors: Eunseok CHO, Suwon-si (KR); Hongwon KIM, Suwon-si (KR); Seunggeol RYU, Suwon-si (KR); Seokwon LEE, Suwon-si (KR); Jaehoon CHOI, Suwon-si (KR); Seungsoo HA, Suwon-si (KR)

(73) Assignee: Samsung Electronics Co., Ltd., Suwon-si (KR)

(21) Appl. No.: 19/213,223

(22) Filed: May 20, 2025

(30) Foreign Application Priority Data
Oct. 4, 2024 (KR) 10-2024-0134985

(51) Int. Cl. H01L 25/16; H01L 21/48; H01L 21/56; H01L 21/683; H01L 23/00; H01L 23/31; H01L 23/367; H01L 23/538; H10B 80/00

(52) U.S. Cl. CPC H10W 90/00; H10B 80/00; H10W 40/228; H10W 70/611; H10W 70/65; H10W 74/121; H10W 90/401; H10P 72/74; H10W 70/023; H10W 72/227; H10W 72/877; H10W 74/016; H10W 74/117; H10W 74/15; H10W 90/20; H10W 90/24; H10W 90/288; H10W 90/722; H10W 90/724; H10W 90/732; H10W 90/734; H10W 90/794

(57) ABSTRACT

A semiconductor package includes a lower connection structure; an intermediate connection structure on the lower connection structure, the intermediate connection structure defining a mounting space therethrough; a first semiconductor device on the lower connection structure, the first semiconductor device being inside the mounting space; a second semiconductor device on the lower connection structure, the second semiconductor device being inside the mounting space, and the second semiconductor device being apart from the first semiconductor device in a horizontal direction. The first semiconductor device includes a plurality of semiconductor chips stacked in a vertical direction perpendicular to the horizontal direction, and vertical connection conductors extending from lower surfaces of each of the plurality of semiconductor chips in the vertical direction. The plurality of semiconductor chips are sequentially stacked offset from each other along the horizontal direction.

### CROSS-REFERENCE TO RELATED APPLICATION

This application is based on and claims ranking under 35 U.S.C. § 119 to Korean Patent Application No. 10-2024-0134985, filed on Oct. 4, 2024, in the Korean Intellectual Property office, the disclosure of which is incorporated by reference herein in its entirety.

### BACKGROUND

The inventive concepts relate to semiconductor packages, and more particularly, to fan-out panel level packages (FOPLPs) and package-on-packages (POPs) including the FOPLPs.

In response to the rapid development of the electronics industry and the desire of users, electronic devices are becoming further miniaturized and multi-functionalized, and as having large capacity. Accordingly, highly integrated semiconductor chips are becoming more advantageous.

Accordingly, to obtain highly integrated semiconductor chips with increased number of connection terminals for input/output (I/O), semiconductor packages including connection terminals having connection reliability has been devised. For example, to limit and/or prevent interference between the connection terminals and/or increase gaps between connection terminals, fan-out semiconductor packages such as fan-out panel level packages have been developed.

### SUMMARY

Some example embodiments of the inventive concepts provide a miniaturized semiconductor package, although the advantages of the inventive concepts are not limited to those mentioned above, and other advantages may be clearly understood by those of ordinary skill in the art from the following description.

Some example embodiments of the inventive concepts provide a semiconductor package that includes a lower connection structure; an intermediate connection structure on the lower connection structure, the intermediate connection structure defining a mounting space therethrough; a first semiconductor device on the lower connection structure, the first semiconductor device being inside the mounting space; a second semiconductor device on the lower connection structure, the second semiconductor device being inside the mounting space, and the second semiconductor device being apart from the first semiconductor device in a horizontal direction; and a molding layer on the lower connection structure, the molding layer surrounding the first semiconductor device and the second semiconductor device. The first semiconductor device includes a plurality of semiconductor chips stacked in a vertical direction perpendicular to the horizontal direction; and vertical connection conductors extending from lower surfaces of the plurality of semiconductor chips in the vertical direction. The plurality of semiconductor chips are sequentially stacked offset from each other along the horizontal direction.

Some example embodiments of the inventive concepts further provide a semiconductor package that includes a lower connection structure including a lower insulating layer, a plurality of lower conductive line patterns on at least one surface of an upper and a lower surface of the lower insulating layer, and a plurality of lower conductive vias penetrating the lower insulating layer, the plurality of lower conductive vias being respectively connected to some of the plurality of lower conductive line patterns; an intermediate connection structure on the lower connection structure, the intermediate connection structure defining a mounting space therethrough; a first semiconductor device on the lower connection structure, the first semiconductor device being inside the mounting space; a second semiconductor device on the lower connection structure, the second semiconductor device being inside the mounting space, and the second semiconductor device being apart from the first semiconductor device in a horizontal direction; a molding layer on the lower connection structure, the molding layer surrounding the first semiconductor device and the second semiconductor device; and a bridge chip inside the lower connection structure and that electrically connects the first semiconductor device to the second semiconductor device. The first semiconductor device includes a plurality of semiconductor chips stacked in a vertical direction perpendicular to the horizontal direction, the plurality of semiconductor chips including chip pads therein; and vertical connection conductors extending from the chip pads of the plurality of semiconductor chips in the vertical direction. The plurality of semiconductor chips are sequentially stacked offset from each other along the horizontal direction.

Some example embodiments of the inventive concepts still further provide a semiconductor package that includes a lower connection structure including a lower insulating layer, a plurality of lower conductive line patterns on at least one of an upper surface and a lower surface of the lower insulating layer, and a plurality of lower conductive vias penetrating the lower insulating layer, the plurality of lower conductive vias being respectively connected to some of the plurality of lower conductive line patterns; an intermediate connection structure on the lower connection structure, the intermediate connection structure defining a mounting space therethrough, the intermediate connection structure including an intermediate insulating layer, a plurality of intermediate conductive line patterns on at least one of an upper surface and a lower surface of the intermediate insulating layer, and a plurality of intermediate conductive vias penetrating the intermediate insulating layer, the plurality of intermediate conductive vias being respectively connected to some of the plurality of intermediate conductive line patterns; a first semiconductor device on the lower connection structure, the first semiconductor device being inside the mounting space; a second semiconductor device on the lower connection structure, the second semiconductor device being inside the mounting space, and the second semiconductor device being apart from the first semiconductor device in a horizontal direction; a molding layer on the lower connection structure, the molding layer surrounding the first semiconductor device and the second semiconductor device; and a bridge chip inside the lower connection structure, the bridge chip electrically connecting the first semiconductor device to the second semiconductor device. The first semiconductor device includes an internal connection structure; a plurality of semiconductor chips on the internal connection structure, the plurality of semiconductor chips being stacked in a vertical direction perpendicular to the horizontal direction, and the plurality of semiconductor chips including chip pads therein; vertical connection conductors extending from the chip pads of the plurality of semiconductor chips in the vertical direction; and an encapsulation material surrounding the plurality of semiconductor chips and the vertical connection conductors. The plurality of semiconductor chips are sequentially stacked offset from each other along the horizontal direction.

Some example embodiments further provide a method of manufacturing a semiconductor package that includes forming an intermediate connection substrate defining a mounting space therethrough; providing a first semiconductor device and a second semiconductor device inside the mounting space, the second semiconductor device being spaced apart from the first semiconductor device in a horizontal direction, and the first semiconductor device including a plurality of semiconductor chips sequentially stacked offset from each other along the horizontal direction; forming a molding layer surrounding side surfaces of the first semiconductor device and side surfaces of the second semiconductor device inside the mounting space; attaching a lower interconnection structure on bottom surfaces of each of the intermediate connection structure, the first semiconductor device and the second semiconductor device; and attaching a heat dissipation plate on an upper surface of the molding layer. The lower connection structure includes a bridge chip embedded therein, and the bridge chip electrically connects the first semiconductor device to the second semiconductor device.

In some example embodiments of the method of manufacturing a semiconductor package, the lower connection structure further includes a bridge connection structure electrically connecting the bridge chip to the first semiconductor device and the second semiconductor device.

In some example embodiments of the method of manufacturing a semiconductor package, the bridge connection structure includes conductive pillars.

In some example embodiments of the method of manufacturing a semiconductor package, the forming of the molding layer further includes covering upper surfaces of each of the intermediate connection structure, the first semiconductor device and the second semiconductor device with the molding layer.

In some example embodiments of the method of manufacturing a semiconductor package, the attaching of the heat dissipation plate further includes contacting the heat dissipation plate to upper surfaces of each of the intermediate connection structure, the first semiconductor device and the second semiconductor device.

In some example embodiments of the method of manufacturing a semiconductor package, upper surfaces of each of the intermediate connection structure, the first semiconductor device and the second semiconductor device are at a same vertical level.

In some example embodiments of the method of manufacturing a semiconductor package, upper surfaces of each of the first semiconductor device and the second semiconductor device are at a vertical level greater than a vertical level of an upper surface of the intermediate connection structure.

In some example embodiments of the method of manufacturing a semiconductor package, the method further includes attaching a passive component to a bottom surface of the lower connection structure.

In some example embodiments of the method of manufacturing a semiconductor package, the intermediate connection structure includes a ground plane and/or a power plane of the semiconductor package.

### BRIEF DESCRIPTION OF THE DRAWINGS

Some example embodiments will be more clearly understood from the following detailed description taken in conjunction with the accompanying drawings in which:

FIG. 1 is a cross-sectional view of a semiconductor package according to some example embodiments;

FIG. 2 is a plan view of a semiconductor package according to some example embodiments;

FIG. 3 is a cross-sectional view of a semiconductor package according to some example embodiments;

FIG. 4 is a cross-sectional view of a semiconductor package according to some example embodiments;

FIG. 5 is a cross-sectional view of a semiconductor package according to some example embodiments;

FIG. 6 is a cross-sectional view of a semiconductor package according to some example embodiments;

FIG. 7 is a cross-sectional view of a package-on-package including a semiconductor package, according to some example embodiments; and

FIGS. 8, 9, 10, 11, 12, 13 and 14 are cross-sectional views describing a method of manufacturing a semiconductor package, according to some example embodiments.

### DETAILED DESCRIPTION

Hereinafter, some example embodiments of the inventive concepts are described in detail with reference to the accompanying drawings. Identical reference numerals are used for the same components in the drawings, and duplicate description thereof will be omitted. In the following drawings, a thickness or size of each layer may be exaggerated for convenience and clarity of description, and thus may differ from an actual shape or ratio.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

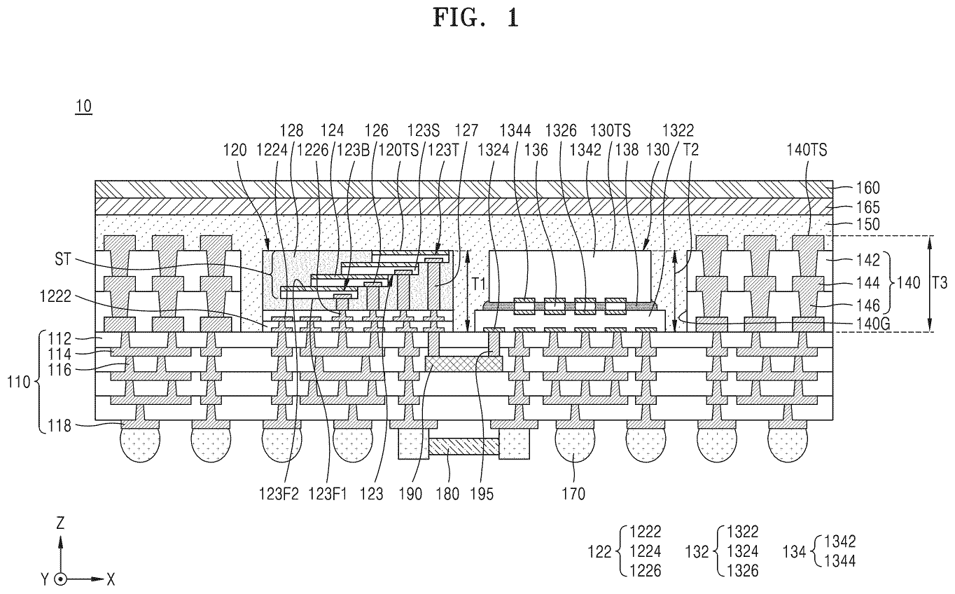

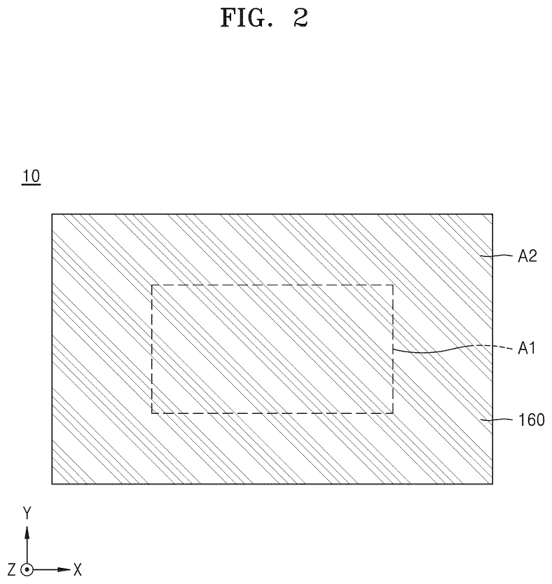

FIG. 1 is a cross-sectional view of a semiconductor package 10 according to some example embodiments. FIG. 2 is a plan view of the semiconductor package 10 according to some example embodiments.

Referring to FIGS. 1 and 2, the semiconductor package 10 according to the inventive concepts may include a lower connection structure 110, a first semiconductor device 120, a second semiconductor device 130, an intermediate connection structure 140, a molding layer 150, and a heat dissipation plate 160. The semiconductor package 10 may include a package of a fan-out structure. A footprint of the lower connection structure 110 may be greater than footprints of the first semiconductor device 120 and the second semiconductor device 130. The footprint of the lower connection structure 110 may be the same as a footprint of the semiconductor package 10.

In the present disclosure, a direction in parallel with a main surface of the lower connection structure 110 may be defined as a horizontal direction (X direction and/or Y direction), and a direction perpendicular to the horizontal direction (X direction and/or Y direction) may be defined as a vertical direction (Z direction).

Among two surfaces apart from each other in the vertical direction (Z-direction), a surface further away from an external connection terminal 170 may be referred to as an upper surface of a component, and a surface opposite to the upper surface may be referred to as a lower surface of the component.

In some example embodiments, the semiconductor package 10 may further include the external connection terminal 170 on a lower surface of the lower connection structure 110. In some example embodiments, the semiconductor package 10 may further include a passive component 180 under the lower surface of the lower connection structure 110.

The lower connection structure 110 may electrically and/or physically connect between the first semiconductor device 120 and the external connection terminal 170. The lower connection structure 110 may electrically and/or physically connect between the second semiconductor device 130 and the external connection terminal 170. The lower connection structure 110 may electrically and/or physically connect between the intermediate connection structure 140 and the external connection terminal 170.

The lower connection structure 110 may include a lower insulating layer 112 (e.g., multilayer), a lower conductive line pattern 114 (e.g., at various different levels), and a lower conductive via 116 (e.g., at various different levels). The lower conductive line pattern 114 may be arranged on one of an upper surface and/or a lower surface of the lower insulating layer 112. The lower conductive via 116 may penetrate the lower insulating layer 112, and may be connected to some of a plurality of lower conductive line patterns 114.

The lower conductive line pattern 114 and the lower conductive via 116 may provide an electrical connection path between the first semiconductor device 120 and the external connection terminal 170. The lower conductive line pattern 114 and the lower conductive via 116 may provide an electrical connection path between the second semiconductor device 130 and the external connection terminal 170.

The lower connection structure 110 may further include a lower pad 118 arranged on a lower surface of the lowermost lower insulating layer 112 of the lower connection structure 110. In some example embodiments, the lower connection structure 110 may further include a lower protection layer covering the lower surface of the lowermost lower insulating layer 112 of the lower connection structure 110. The lower connection structure 110 may include a redistribution structure or a printed circuit board (PCB).

The lower insulating layer 112 may include, for example, an inorganic insulating material, an organic insulating material, or a combination thereof. The inorganic insulating material may include, for example, silicon oxide, silicon nitride, or a combination thereof. The organic insulating material may include, for example, polyimide, epoxy resin, or a combination thereof. The lower conductive line pattern 114 and the lower conductive via 116 may each include a conductive material that may include, for example, copper (Cu), gold (Au), silver (Ag), nickel (Ni), tungsten (W), aluminum (Al), or a combination thereof. In some example embodiments, the lower conductive line pattern 114 and the lower conductive via 116 may each further include a barrier material for limiting and/or preventing the conductive material from diffusing outside the lower conductive line pattern 114 and the lower conductive via 116. The barrier material may include, for example, titanium (Ti), tantalum (Ta), titanium nitride (TiN), tantalum nitride (TaN), or a combination thereof.

In some example embodiments, the lower conductive via 116 may have a tapered shape having width along the horizontal direction (X direction) that increases away from the first semiconductor device 120 and/or the second semiconductor device 130 in the vertical direction (Z direction). In some example embodiments, the lower conductive via 116 may have a tapered shape having width along the horizontal direction (X direction) that decreases away from the first semiconductor device 120 and/or the second semiconductor device 130 in the vertical direction (Z direction). The shape of the lower conductive via 116 may vary according to the process sequence of the semiconductor package 10. The shape of the lower conductive via 116 may vary according to the mounting sequence of the first semiconductor device 120 and the second semiconductor device 130 and the formation order of the lower connection structure 110.

The lower protection layer may physically and/or chemically protect the lower connection structure 110 from the surrounding environment. In some example embodiments, the lower protection layer may include a composite material. For example, the lower protection layer may include a matrix and a filler in the matrix. The matrix may include a polymer, and the filler may include silica, titania, or a combination thereof.

The lower pad 118 may be in contact with the lower conductive via 116 to connect between the lower conductive via 116 and the external connection terminal 170. The lower pad 118 may include a conductive material, for example, copper (Cu), gold (Au), silver (Ag), nickel (Ni), tungsten (W), aluminum (Al), or a combination thereof. In some example embodiments, the lower pad 118 may further include a barrier material for limiting and/or preventing the conductive material from diffusing to the outside of the lower pad 118. The barrier material may include, for example, titanium (Ti), tantalum (Ta), titanium nitride (TiN), tantalum nitride (TaN), or a combination thereof. In some example embodiments, the lower pad 118 may further include a wetting material for improving wettability between the conductive material and the external connection terminal 170. When the conductive material includes Cu, the wetting material may for example include Ni, Au, or a combination thereof.

The first semiconductor device 120 and/or the second semiconductor device 130 may be mounted on the lower connection structure 110. In some example embodiments, the first semiconductor device 120 and the second semiconductor device 130 may be arranged apart from each other on the lower connection structure 110 in the horizontal direction (X direction and/or Y direction). For example, the first semiconductor device 120 and the second semiconductor device 130 may be arranged side-by-side on the lower connection structure 110. Each of the first semiconductor device 120 and the second semiconductor device 130 may be arranged apart from the intermediate connection structure 140 in the horizontal direction (X direction and/or Y direction).

The first semiconductor device 120 may include an internal connection structure 122, a plurality of semiconductor chips 123, a vertical connection conductor 127, and an encapsulation member 128. The first semiconductor device 120 may have a first thickness T1, which is a vertical distance from an upper surface of the lower connection structure 110 to an upper surface 120TS of the first semiconductor device 120. The plurality of semiconductor chips 123 may form a semiconductor chip stack ST.

The internal connection structure 122 may be arranged between the lower connection structure 110 and the semiconductor chip stack ST. The internal connection structure 122 may electrically and/or physically connect the lower connection structure 110 to the semiconductor chip stack ST. The internal connection structure 122 may include an internal insulating layer 1222, an internal conductive line pattern 1224, and an internal conductive via 1226. The internal connection structure 122 may include a redistribution structure and/or a printed circuit board.

The internal conductive line pattern 1224 may be arranged on one surface of an upper surface and/or a lower surface of the internal insulating layer 1222. The internal conductive via 1226 may penetrate the internal insulating layer 1222, and may be connected to a portion of a plurality of internal conductive line patterns 1224. The internal conductive line pattern 1224 and the internal conductive via 1226 may provide an electrical connection path between the lower connection structure 110 and the semiconductor chip stack ST. The internal insulating layer 1222 may include, for example, an inorganic insulating material, an organic insulating material, or a combination thereof. The inorganic insulating material may include, for example, silicon oxide, silicon nitride, or a combination thereof. The organic insulating material may include, for example, polyimide, epoxy resin, or a combination thereof. The lower conductive line pattern 114 and the internal conductive via 1226 may include a conductive material including, for example, Cu, Au, Ag, Ni, W, Al, or a combination thereof. In some example embodiments, the internal conductive line pattern 1224 and the internal conductive via 1226 may further include a barrier material for limiting and/or preventing the conductive material from diffusing to the outside of the internal conductive line pattern 1224 and the internal conductive via 1226. The barrier material may include, for example, titanium (Ti), tantalum (Ta), titanium nitride (TiN), tantalum nitride (TaN), or a combination thereof.

In some example embodiments, the internal conductive via 1226 may have a tapered shape having width along the horizontal direction (X direction) that increases away from the semiconductor chip stack ST in the vertical direction (Z direction). In some example embodiments, the internal conductive via 1226 may have a tapered shape having width along the horizontal direction (X direction) that decreases away from the semiconductor chip stack ST in the vertical direction (Z direction). The shape of the internal conductive via 1226 may vary according to the process sequence of the first semiconductor device 120.

The plurality of internal conductive line patterns 1224 at the lowest vertical level among the plurality of internal conductive line patterns 1224 may be in contact with the lower conductive via 116 of the lower connection structure 110.

The plurality of semiconductor chips 123 constituting the semiconductor chip stack ST may be stacked in a step manner. For example, the semiconductor chip stack ST may include the plurality of semiconductor chips 123 which are offset in the horizontal direction (X direction and/or Y direction) and are sequentially stacked. The plurality of semiconductor chips 123 may be arranged with an offset stacking direction in the horizontal direction (X direction and/or Y direction). In some example embodiments, the offset stacking direction may be defined as a direction, in which a semiconductor chip is shifted with respect to another semiconductor chip under the semiconductor chip when the semiconductor chips are stacked. For example, the plurality of semiconductor chips 123 may have the offset stacking direction in the first horizontal direction (X direction).

The semiconductor chip 123 may include a semiconductor substrate 123S. The semiconductor chip 123 may include an active surface, which is one surface facing the internal connection structure 122, and a rear surface 123F2 positioned opposite the active surface. The active surface of the semiconductor chip 123 may be arranged adjacent to a front surface 123F1 of the semiconductor chip 123. In some example embodiments, the semiconductor chip 123 may have a face down arrangement, in which the active surface including devices of the semiconductor chip 123 arranged on the active surface faces the internal connection structure 122, and the semiconductor chip stack ST may be mounted on the internal connection structure 122.

The semiconductor substrate 123S may include, for example, silicon (Si). Alternatively, the semiconductor substrate 123S may include a semiconductor element, such as germanium (Ge), or a compound semiconductor such as silicon carbide (SiC), gallium arsenide (GaAs), indium arsenide (InAs), and indium phosphide (InP).

The semiconductor chip 123 may include, for example, a dynamic random access memory (RAM) (DRAM) chip, a static RAM (SRAM) chip, a flash memory chip, an electrically erasable and programmable read-only memory (ROM) (EEPROM) chip, a phase-change RAM (PRAM) chip, a magnetic RAM (MRAM) chip, or a resistive RAM (RRAM) chip.

An adhesive layer 124 may be arranged on each of the rear surfaces 123F2 of a plurality of semiconductor chips 123. The adhesive layer 124 may fully cover the rear surface 123F2 of the semiconductor chip 123 to which the adhesive layer 124 is attached, or at least a portion of the rear surface 123F2 of the semiconductor chip 123 to which the adhesive layer 124 is attached. The adhesive layer 124 arranged on each of the rear surfaces 123F2 of the plurality of semiconductor chips 123 except for an uppermost semiconductor chip 123T may be arranged between a semiconductor chip 123 and another semiconductor chip 123 stacked on the semiconductor chip 123. The adhesive layer 124 may include die attach film (DAF).

A plurality of chip pads 126 may be provided on the front surface 123F1 of the semiconductor chip 123. The plurality of chip pads 126 may be electrically connected to other components within the semiconductor chip 123, for example, an integrated circuit. Memory devices and a multi-wiring layer may be formed in a lower region of the semiconductor substrate 123S, for example an active region, and the plurality of chip pads 126 may be electrically connected to an integrated circuit inside the semiconductor chip 123 via the multi-wiring layer.

The vertical connection conductor 127 may be arranged between the semiconductor chip 123 and the internal connection structure 122. The vertical connection conductor 127 may be formed to extend in the vertical direction (Z direction) from the active surface of the semiconductor chip 123 to an upper surface of the internal connection structure 122. The vertical connection conductor 127 may electrically connect the semiconductor chip 123 to the internal connection structure 122. The vertical connection conductor 127 may be in contact with the internal conductive via 1226 of the internal connection structure 122. The vertical connection conductor 127 may be in contact with a chip pad 126 of the semiconductor chip 123. The vertical connection conductor 127 may include a conductive material of Cu, Au, Ag, Ni, tungsten (W), Al, or a combination thereof.

The encapsulation member 128 may surround at least a portion of a surface of the semiconductor chip stack ST., the encapsulation member 128 may surround side surfaces of the vertical connection conductor 127, and may be in contact with the upper surface of the internal connection structure 122. Side surfaces of the encapsulation member 128 may be aligned with side surfaces of the internal connection structure 122 in the vertical direction (Z direction). An upper surface of the encapsulation member 128 may have the same vertical level as an upper surface of the uppermost semiconductor chip 123T or the adhesive layer 124 arranged on the upper surface of the uppermost semiconductor chip 123T. The encapsulation member 128 may include, for example, an epoxy molding compound (EMC) or a polymer material.

Among the plurality of semiconductor chips 123, the other semiconductor chips 123 except for a lowermost semiconductor chip 123B may be offset in the horizontal direction (X direction and/or Y direction), and a portion of the front surface 123F1 of the semiconductor chip 123 exposed by being offset laterally from another semiconductor chip 123 located directly over the semiconductor chip 123 may be in contact with the encapsulation member 128.

Although FIG. 1 exemplarily illustrates that the first semiconductor device 120 includes four semiconductor chips 123, the technical idea of the inventive concepts is not limited thereto. For example, the first semiconductor device 120 may also include five or more semiconductor chips 123, or may include three or less semiconductor chips 123.

The second semiconductor device 130 may include a lower semiconductor chip 132 and an upper semiconductor chip 134. The second semiconductor device 130 may be electrically and/or physically connected to the lower conductive via 116 of the lower connection structure 110 via a first lower chip pad 1324. In some example embodiments, the second semiconductor device 130 may have a three-dimensional (3D) stacked structure including a plurality of semiconductor chips stacked on each other in the vertical direction (Z direction).

The second semiconductor device 130 may have a second thickness T2, which is a vertical distance from the upper surface of the lower connection structure 110 to an upper surface 130TS of the second semiconductor device 130. In some example embodiments, the first thickness T1 of the first semiconductor device 120 may be the same as a second thickness T2 of the second semiconductor device 130. In some example embodiments, the first thickness T1 of the first semiconductor device 120 may be the different from the second thickness T2 of the second semiconductor device 130.

The lower semiconductor chip 132 may include a lower semiconductor substrate 1322, the first lower chip pad 1324, and an upper chip pad 1326. The upper semiconductor chip 134 may include an upper semiconductor substrate 1342 and a second lower chip pad 1344. The first lower chip pad 1324 may be provided in a lower region of the lower semiconductor substrate 1322, the upper chip pad 1326 may be provided in an upper region of the lower semiconductor substrate 1322, and the second lower chip pad 1344 may be provided in a lower region of the upper semiconductor substrate 1342.

The lower semiconductor chip 132 may further include through electrodes (not shown) penetrating the lower semiconductor substrate 1322 and electrically connecting the first lower chip pad 1324 to the upper chip pad 1326.

The upper chip pad 1326 of the lower semiconductor chip 132 may be electrically and/or physically connected to the second lower chip pad 1344 of the upper semiconductor chip 134 via an inter-chip connection bump 136. A gap-fill insulating layer 138 surrounding the inter-chip connection bump 136 may be formed between the lower semiconductor chip 132 and the upper semiconductor chip 134. The gap-fill insulating layer 138 may include, for example, non-conductive film (NCF).

The lower semiconductor substrate 1322 and the upper semiconductor substrate 1342 may include, for example, silicon (Si). Alternatively, the lower semiconductor substrate 1322 and the upper semiconductor substrate 1342 may include a semiconductor element such as germanium (Ge), or a compound semiconductor such as silicon carbide (SiC), gallium arsenide (GaAs), indium arsenide (InAs), and indium phosphide (InP).

Although FIG. 1 exemplarily illustrates that the second semiconductor device 130 includes two semiconductor chips, the technical idea of the inventive concepts is not limited thereto. For example, the second semiconductor device 130 may also include three or more semiconductor chips stacked in the vertical direction (Z direction), or may also include a single semiconductor chip.

After the first semiconductor device 120 and/or the second semiconductor device 130 is mounted, the semiconductor package 10 of the inventive concepts may be formed in a chip-first manner in which the lower connection structure 110 is formed later. Accordingly, the first semiconductor device 120 and/or the second semiconductor device 130 may be in contact with the lower connection structure 110.

The intermediate connection structure 140 may be on the lower connection structure 110, and may be arranged apart from each of the first semiconductor device 120 and the second semiconductor device 130 in the horizontal direction (X direction and/or Y direction). In some example embodiments, the intermediate connection structure 140 may include a mounting space 140G, and the first semiconductor device 120 and the second semiconductor device 130 may be inside the mounting space 140G of the intermediate connection structure 140. For example, the intermediate connection structure 140 may include the mounting space 140G in which the first semiconductor device 120 and/or the second semiconductor device 130 is mounted. For example, the intermediate connection structure 140 may define the mounting space 140G therethrough. For example, the intermediate connection structure 140 may surround the first semiconductor device 120 and the second semiconductor device 130. For example, in a plan view, a first region A1 in which the first semiconductor device 120 and/or the second semiconductor device 130 is arranged may be surrounded by a second region A2 in which the intermediate connection structure 140 is arranged.

The intermediate connection structure 140 may include one or more intermediate insulating layers 142, an intermediate conductive line pattern 144, and an intermediate conductive via 146 stacked in the vertical direction (Z direction). The intermediate conductive line pattern 144 may be arranged on one of an upper surface and/or a lower surface of the intermediate insulating layer 142. The intermediate conductive via 146 may penetrate the intermediate insulating layer 142, and may be connected to some of the plurality of intermediate conductive line patterns 144. The intermediate connection structure 140 may be electrically connected to the lower connection structure 110 via the intermediate conductive line pattern 144 and the intermediate conductive via 146. For example, the intermediate conductive line pattern 144 and the intermediate conductive via 146 may provide an electrical path through which the intermediate connection structure 140 is connected to the lower connection structure 110.

The intermediate connection structure 140 may have a third thickness T3, which is a vertical distance from the upper surface of the lower connection structure 110 to an upper surface 140TS of the intermediate connection structure 140. In some example embodiments, the third thickness T3 of the intermediate connection structure 140 may be greater than the first thickness T1 of the first semiconductor device 120 and/or the second thickness T2 of the second semiconductor device 130.

Although FIG. 1 illustrates for example that the intermediate connection structure 140 includes two intermediate insulating layers 142, the technical idea of the inventive concepts is not limited thereto. For example, the intermediate connection structure 140 may include one intermediate insulating layer 142 or three or more intermediate insulating layers 142.

The intermediate insulating layer 142 may include an insulating material. A thermosetting resin such as an epoxy resin, a thermoplastic resin such as polyimide, or an insulating material, in which the resin is impregnated into a core material, such as an inorganic filler and/or fiberglass (glass fiber, glass cloth, glass fabric), for example, prepreg, Ajinomoto Build-up Film (ABF), FR-4, Bismaleimide Triazine (BT), etc. may be used as the insulating material. The intermediate conductive line pattern 144 and the intermediate conductive via 146 may include, for example, Cu, Au, Ag, Ni, W, Al, or a combination thereof. In some example embodiments, the intermediate conductive line pattern 144 and the intermediate conductive via 146 may further include a barrier material for limiting and/or preventing the conductive material from diffusing to the outside of the intermediate conductive line pattern 144 and the intermediate conductive via 146. The barrier material may include, for example, Ti, Ta, TiN, TaN, or a combination thereof.

The intermediate connection structure 140 may be electrically connected to the lower connection structure 110, and function as a ground plane and/or a power plane of the semiconductor package 10. Accordingly, the intermediate connection structure 140 may increase the design feasibility, flexibility and/or layout of the semiconductor package 10.

The molding layer 150 may be arranged above the lower connection structure 110. The molding layer 150 may cover the upper surface of each of the first semiconductor device 120, the second semiconductor device 130, and the intermediate connection structure 140. Accordingly, an upper surface of the molding layer 150 may be at a vertical level higher than the upper surface of each of the first semiconductor device 120, the second semiconductor device 130, and the intermediate connection structure 140.

The molding layer 150 may include, for example, a thermosetting resin such as an epoxy resin or a thermoplastic resin such as polyimide. A molding material such as epoxy mold compounds (EMCs) or a photosensitive material such as photoimageable encapsulant (PIE) may be used. In some example embodiments, the molding layer 150 may include a matrix and a composite material including a filler in the matrix. The matrix may include a polymer, and the filler may include silica, titania, or a combination thereof.

The heat dissipation plate 160 may be attached onto the molding layer 150. The heat dissipation plate 160 may overlap each of the first semiconductor device 120 and/or the second semiconductor device 130 in the vertical direction (Z direction). In some example embodiments, a footprint of the heat dissipation plate 160 may be the same or substantially the same as a footprint of the lower connection structure 110. For example, the heat dissipation plate 160 may cover the entire upper surface of the molding layer 150. For example, the heat dissipation plate 160 may have a rectangular shape. In some example embodiments, in a plan view, the heat dissipation plate 160 may have a symmetric shape.

The heat dissipation plate 160 may include a heat sink, a heat pipe, and/or a heat slug. Heat generated by the first semiconductor device 120 and/or the second semiconductor device 130 may be discharged to the outside of the semiconductor package 10 via the molding layer 150 and the heat dissipation plate 160. The heat dissipation plate 160 may include a heat conductive material having high thermal conductivity. The thermal conductivity of a material constituting the heat dissipation plate 160 may be greater than the thermal conductivity of Si. For example, the heat resistance of the material constituting the heat dissipation plate 160 may be less than the heat resistance of Si. For example, the heat dissipation plate 160 may include a metal, such as Cu and Al, or a carbon-containing material, such as graphene, graphite, and/or carbon nanotube.

The heat dissipation plate 160 may be attached onto the molding layer 150 by using a thermally conductive adhesive layer 165. The thermally conductive adhesive layer 165 may include a thermally conductive and electrically insulating material. The thermally conductive adhesive layer 165 may include a thermal interface material, a polymer including metal powder, thermal grease, or a combination thereof.

The external connection terminal 170 may be arranged under a lower surface of the lower pad 118 of the lower connection structure 110. The external connection terminal 170 may include, for example, a conductive material including tin (Sn), lead (Pb), Ag, Cu, or a combination thereof. The external connection terminal 170 may be formed by using, for example, a solder ball. The external connection terminal 170 may connect the semiconductor package 10 to a circuit board, another semiconductor package, an interposer, or a combination thereof.

The passive component 180 may stabilize power. The passive component 180 may be connected to the lower connection structure 110 via the lower pad 118 of the lower connection structure 110. For example, the passive component 180 may include a capacitor.

The semiconductor package 10 may further include a bridge chip 190. In some example embodiments, the bridge chip 190 may be arranged at a vertical level lower than the first semiconductor device 120 and/or the second semiconductor device 130. For example, the bridge chip 190 may be arranged inside the lower connection structure 110. For example, the bridge chip 190 may be embedded inside the lower connection structure 110. The bridge chip 190 may function as a bridge electrically connecting the first semiconductor device 120 to the second semiconductor device 130, and may have a pitch (e.g., length along the X direction) corresponding to a fine pitch (e.g., distance along the X direction) between each of the first semiconductor device 120 and the second semiconductor device 130.

The bridge chip 190 may include a bridge circuit therein. The bridge circuit may have a pitch corresponding to the pitch of each of the different semiconductor devices, and may function as a bridge to electrically connect the semiconductor devices to each other.

The bridge chip 190 may be arranged apart from the upper surface of the lower connection structure 110 in the vertical direction (Z direction). In some example embodiments, the bridge chip 190 may be arranged apart from the uppermost lower insulating layer 112 of the lower connection structure 110 in the vertical direction (Z direction). In some example embodiments, the bridge chip 190 may be arranged inside the uppermost lower insulating layer 112 of the lower connection structure 110.

The bridge chip 190 may be electrically connected to the first semiconductor device 120 and/or the second semiconductor device 130. A bridge connection structure 195 may be arranged between the bridge chip 190 and the first semiconductor device 120, and/or between the bridge chip 190 and the second semiconductor device 130. For example, the bridge connection structure 195 may include a pillar and/or a conductive bump.

The semiconductor package 10 of the inventive concepts may include the first semiconductor device 120 and the second semiconductor device 130 mounted side by side thereon, and accordingly, the size of the semiconductor package 10 may be reduced.

The semiconductor package 10 of the inventive concepts may include the intermediate connection structure 140. The thickness of the intermediate connection structure 140 may be controlled according to various thicknesses of the first semiconductor device 120, and thus various dimension of the first semiconductor device 120 may be accommodated. By including the intermediate connection structure 140, the thickness of the lower connection structure 110 may be reduced.

Furthermore, by including the heat dissipation plate 160 which entirely covers the upper surface of the molding layer 150, the mechanical and/or thermal stability of the semiconductor package 10 may be increased. Heat generated by the semiconductor package 10 may be effectively discharged to the outside of the semiconductor package 10.

The semiconductor package 10 of the inventive concepts may include the bridge chip 190. The bridge chip 190 may provide a pitch corresponding to the fine pitches of the first semiconductor device 120 and the second semiconductor device 130. For example, by using bridge chip 190, a fine pitch may be realized between the first semiconductor device 120 and the second semiconductor device 130.

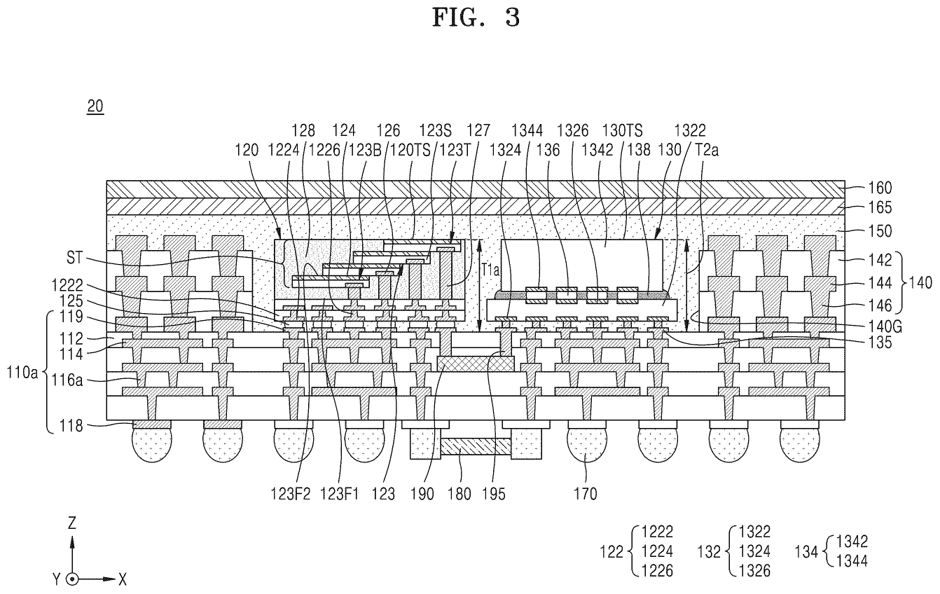

FIG. 3 is a cross-sectional view of a semiconductor package 20 according to some example embodiments.

The semiconductor package 20 illustrated in FIG. 3 may be almost the same as or similar to the semiconductor package 10 illustrated in FIG. 1, except that the semiconductor package 20 includes a first connection member 125 and a second connection member 135. Accordingly, descriptions of the components already given with reference to FIGS. 1 and 2 are omitted or simplified.

Referring to FIG. 3, a lower connection structure 110a may include the lower insulating layer 112, the lower conductive line pattern 114, a lower conductive via 116a, the lower pad 118, and an upper pad 119. In some example embodiments, the lower conductive via 116a may have a tapered shape having width along the horizontal direction (X direction) that decreases away from the first semiconductor device 120 and/or the second semiconductor device 130 in the vertical direction (Z direction). In some example embodiments, the lower conductive via 116a may have a tapered shape having width along the horizontal direction (X direction) that increases away from the first semiconductor device 120 and/or the second semiconductor device 130 in the vertical direction (Z direction).

The upper pad 119 may be arranged on the upper surface of the uppermost lower insulating layer 112. The upper pad 119 may be electrically connected to the lower conductive line pattern 114 and the lower conductive via 116a. The upper pad 119 may include a conductive material, for example, Cu, Au, Ni, W, Al, or a combination thereof. In some example embodiments, the upper pad 119 may further include a barrier material for limiting and/or preventing the conductive material from diffusing to the outside of the upper pad 119. The barrier material may include, for example, Ti, Ta, TiN, TaN, or a combination thereof.

The first connection member 125 may be arranged between the lower connection structure 110a and the first semiconductor device 120. The second connection member 135 may be arranged between the lower connection structure 110a and the second semiconductor device 130. The first connection member 125 may electrically and/or physically connect the lower connection structure 110a to the first semiconductor device 120. The second connection member 135 may electrically and/or physically connect the lower connection structure 110a to the second semiconductor device 130.

The first connection member 125 and/or the second connection member 135 may include a connection pad. For example, the first connection member 125 and/or the second connection member 135 may include a conductive pillar and/or a solder bump. Although FIG. 3 illustrates that the first connection member 125 includes for example a solder bump, and the second connection member 135 includes for example a conductive pillar, the inventive concepts are not limited thereto.

In the semiconductor package 20 of FIG. 3, a first thickness T1a, which is a vertical distance from the upper surface of the uppermost lower insulating layer 112 to the upper surface 120TS of the first semiconductor device 120, may be the same as a second thickness T2a, which is a vertical distance from the upper surface of the uppermost lower insulating layer 112 to an upper surface 130TS of the second semiconductor device 130.

The semiconductor package 20 of the inventive concepts may be formed in a chip-last method in which the first semiconductor device 120 and/or the second semiconductor device 130 is mounted after the lower connection structure 110a is formed. Accordingly, the first connection member 125 may be arranged between the first semiconductor device 120 and the lower connection structure 110a, and the second connection member 135 may be arranged between the second semiconductor device 130 and the lower connection structure 110a, providing design and/or layout flexibility.

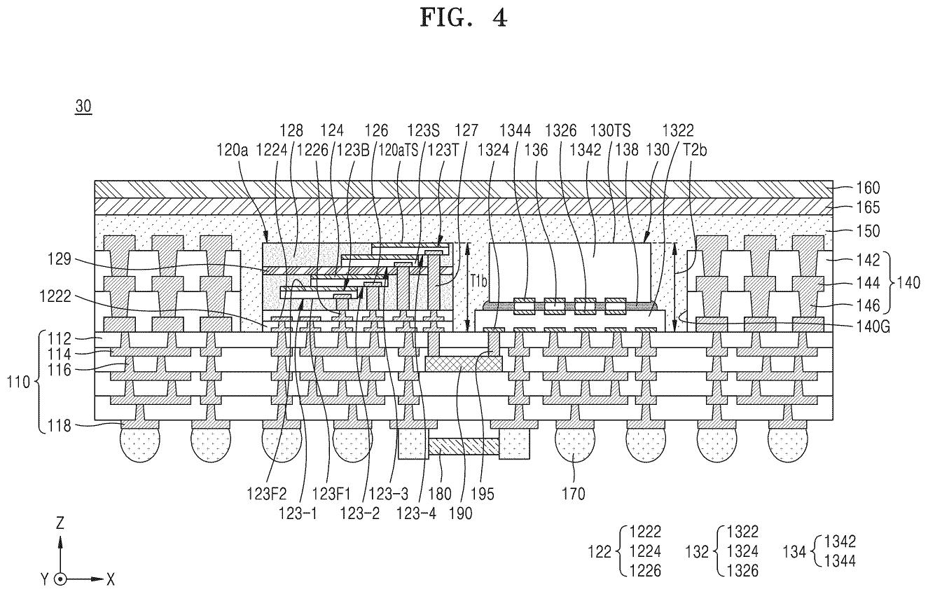

FIG. 4 is a cross-sectional view of a semiconductor package 30 according to some example embodiments.

The semiconductor package 30 illustrated in FIG. 4 may be almost the same as or similar to the semiconductor package 10 illustrated in FIG. 1, except that an additional insulating layer 129 is further included. Accordingly, descriptions of the components already given with reference to FIGS. 1 and 2 are omitted or simplified.

Referring to FIG. 4, a first semiconductor device 120a may include the internal connection structure 122, the plurality of semiconductor chips 123, the vertical connection conductor 127, the encapsulation member 128, and the additional insulating layer 129. Hereinafter, for convenience of description, in the first semiconductor device 120a, the plurality of semiconductor chips 123 may be referred to as first through fourth semiconductor chips 123-1 through 123-4 in the order of being close to the internal connection structure 122 in the vertical direction (Z direction).

The additional insulating layer 129 may be arranged between the plurality of semiconductor chips 123. The additional insulating layer 129 may be arranged on the upper surface of at least one semiconductor chip 123 among the plurality of semiconductor chips 123. For example, the additional insulating layer 129 may be arranged on an upper surface of the second semiconductor chip 123-2. In some example embodiments, the additional insulating layer 129 may be arranged on the adhesive layer 124 arranged on the upper surface of the second semiconductor chip 123-2. In some example embodiments, the additional insulating layer 129 may be arranged on the first semiconductor chip 123-1 and/or the third semiconductor chip 123-3.

For convenience of description, the semiconductor chips at vertical levels lower than the additional insulating layer 129 in the first semiconductor device 120a may be collectively referred to as lower semiconductor structures, and the semiconductor chips at vertical levels higher than the additional insulating layer 129 in the first semiconductor device 120a may be collectively referred to as upper semiconductor structures. A footprint of the additional insulating layer 129 may be the same as the footprint of the first semiconductor device 120a.

The additional insulating layer 129 may include an insulating material. For example, the additional insulating layer 129 may include a dielectric material. For example, the additional insulating layer 129 may include photo imageable dielectric (PID).

At least some of the plurality of vertical connection conductors 127 may penetrate the additional insulating layer 129 in the vertical direction (Z direction). Among the plurality of vertical connection conductors 127, the vertical connection conductors 127 contacting the upper semiconductor structures may penetrate the additional insulating layer 129 in the vertical direction (Z direction). In some example embodiments, the first semiconductor device 120a may further include a connection structure, which overlaps the vertical connection conductor 127 in the vertical direction (Z direction) and is in contact with the vertical connection conductor 127, inside the additional insulating layer 129.

In some example embodiments, the encapsulation member 128 surrounding the lower semiconductor structure may be the same as the encapsulation member 128 surrounding the upper semiconductor structure. In some example embodiments, the encapsulation member 128 surrounding the lower semiconductor structure may be different from the encapsulation member 128 surrounding the upper semiconductor structure.

In the semiconductor package 30 of FIG. 4, a first thickness T1b, which is a vertical distance from the upper surface of the lower connection structure 110 to an upper surface 120aTS of the first semiconductor device 120a may be the same as a second thickness T2b, which is a vertical distance from the upper surface of the lower connection structure 110 to the upper surface 130TS of the second semiconductor device 130.

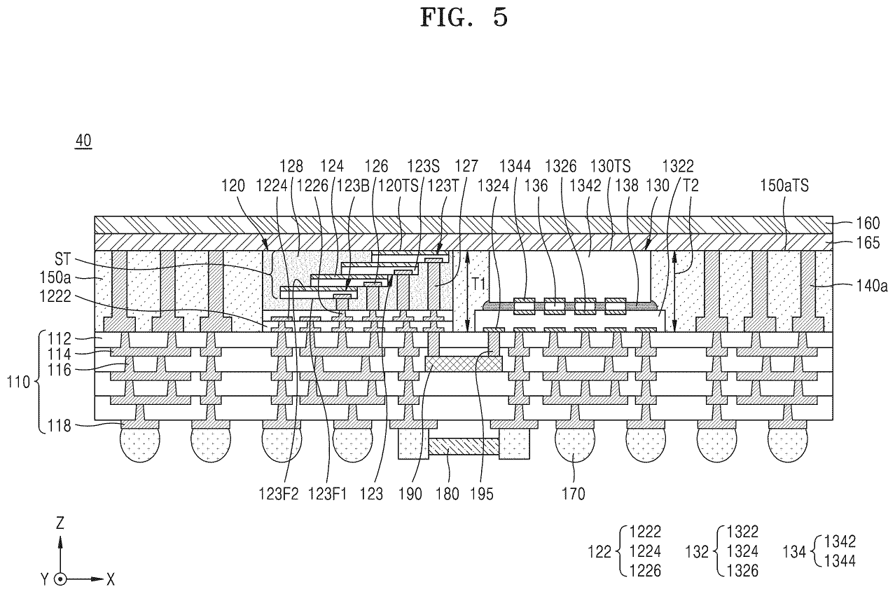

FIG. 5 is a cross-sectional view of a semiconductor package 40 according to some example embodiments.

The semiconductor package 40 illustrated in FIG. 5 may be almost the same as or similar to the semiconductor package 10 illustrated in FIG. 1, except that an intermediate connection structure 140a includes a conductive post. Accordingly, descriptions of the components already given with reference to FIGS. 1 and 2 are omitted or simplified.

Referring to FIG. 5, the intermediate connection structure 140a may penetrate a molding layer 150a, and may be arranged between the lower connection structure 110 and the heat dissipation plate 160. For example, the intermediate connection structure 140a may include a through mold via (TMV), a conductive solder, a conductive pillar, or at least one conductive bump.

The molding layer 150a may surround the intermediate connection structure 140a. An upper surface 150aTS of the molding layer 150a may be at the same vertical level as each of the upper surface 120TS of the first semiconductor device 120, the upper surface 130TS of the second semiconductor device 130, and/or an upper surface of the intermediate connection structure 140a. For example, the upper surface 120TS of the first semiconductor device 120, the upper surface 130TS of the second semiconductor device 130, and/or the upper surface of the intermediate connection structure 140a may be in contact with the thermally conductive adhesive layer 165.

Because the upper surface 150aTS of the molding layer 150a is at the same vertical level as each of the upper surface 120TS of the first semiconductor device 120 and/or the upper surface 130TS of the second semiconductor device 130, heat generated by the first semiconductor device 120 and/or the second semiconductor device 130 may be easily discharged to the outside of the semiconductor package 40.

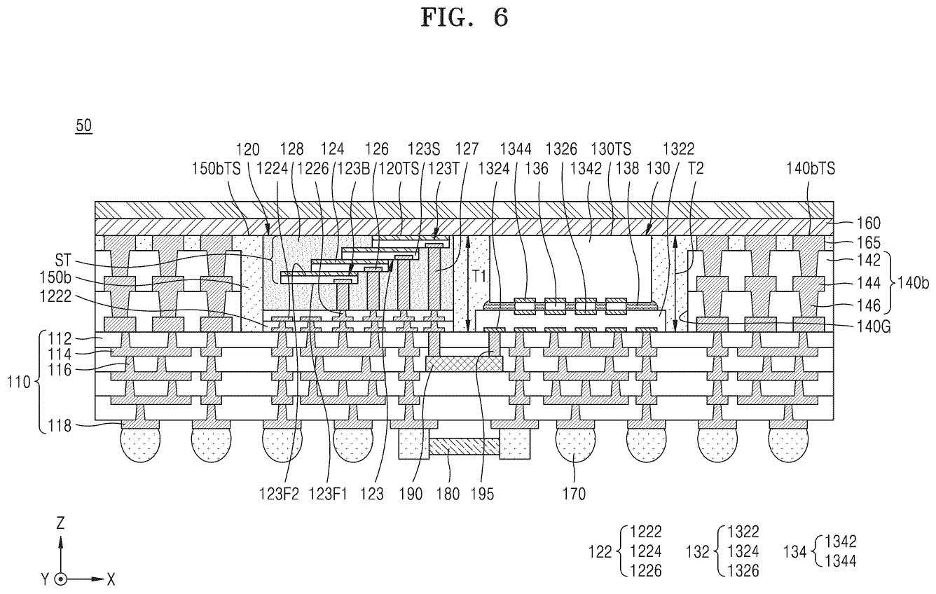

FIG. 6 is a cross-sectional view of a semiconductor package 50 according to some example embodiments.

The semiconductor package 50 illustrated in FIG. 6 may be almost the same as or similar to the semiconductor package 10 illustrated in FIG. 1 except that an upper surface 150bTS of a molding layer 150b is at the same vertical level as each of the upper surface 120TS of the first semiconductor device 120, the upper surface 130TS of the second semiconductor device 130, and/or an upper surface 140bTS of an intermediate connection structure 140b. Accordingly, descriptions of the components already given with reference to FIGS. 1 and 2 are omitted or simplified.

Referring to FIG. 6, the upper surface 150bTS of the molding layer 150b may be at the same vertical level as each of the upper surface 120TS of the first semiconductor device 120, the upper surface 130TS of the second semiconductor device 130, and/or an upper surface 140bTS of the intermediate connection structure 140b. For example, the upper surface 120TS of the first semiconductor device 120, the upper surface 130TS of the second semiconductor device 130, and/or the upper surface 140bTS of the intermediate connection structure 140b may be in contact with the thermally conductive adhesive layer 165.

Because the upper surface 150bTS of the molding layer 150b is at the same vertical level as each of the upper surface 120TS of the first semiconductor device 120 and/or the upper surface 130TS of the second semiconductor device 130, heat generated by the first semiconductor device 120 and/or the second semiconductor device 130 may be easily discharged to the outside of the semiconductor package 50.

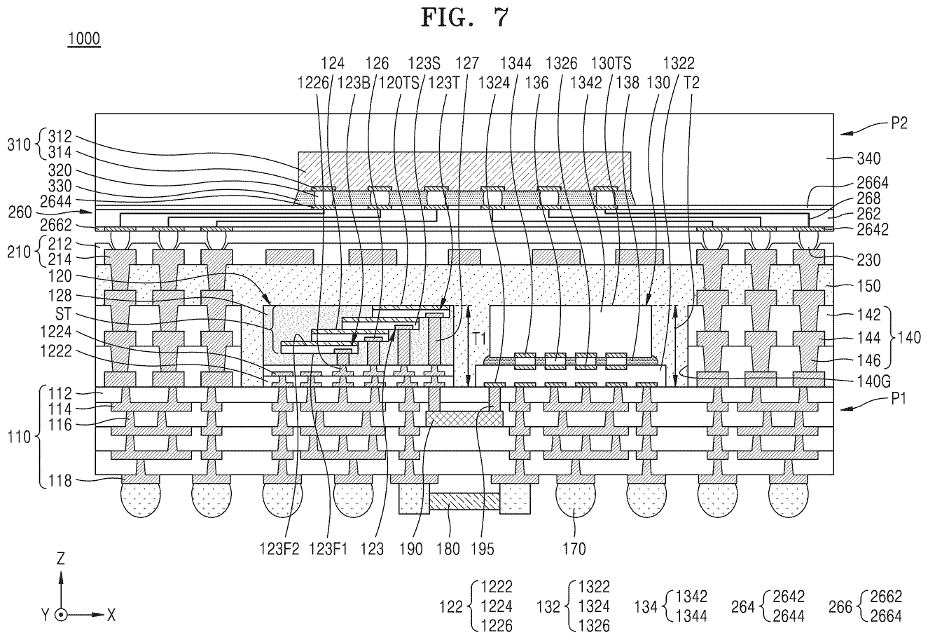

FIG. 7 is a cross-sectional view of a package-on-package 1000 including a semiconductor package, according to some example embodiments. Descriptions are given with reference to FIG. 1 together.

Referring to FIG. 7, the package-on-package 1000 may include a second semiconductor package P2 stacked on a first semiconductor package P1. The first semiconductor package P1 may include a lower semiconductor package, and the second semiconductor package P2 may include an upper semiconductor package.

The first semiconductor package P1 may include the lower connection structure 110, the first semiconductor device 120, the second semiconductor device 130, the intermediate connection structure 140, the molding layer 150, and an upper connection structure 210. The lower connection structure 110, the first semiconductor device 120, the second semiconductor device 130, the intermediate connection structure 140, and the molding layer 150 of the first semiconductor package P1 in FIG. 7 may be the same or substantially the same as or similar to the lower connection structure 110, the first semiconductor device 120, the second semiconductor device 130, the intermediate connection structure 140, and the molding layer 150 in FIG. 1, respectively, and thus the first semiconductor package P1 is described mainly with respect to the upper connection structure 210.

The intermediate conductive via 146 may penetrate the intermediate insulating layer 142 and/or the molding layer 150, and may be connected to some of a plurality of intermediate conductive line patterns 144.

The upper connection structure 210 may include an upper insulating layer 212 and an upper conductive line pattern 214. The upper conductive line pattern 214 may be arranged on one of an upper surface and/or a lower surface of the upper insulating layer 212. Although not illustrated in FIG. 7, the upper connection structure 210 may further include an upper conductive via. The upper conductive via may penetrate the upper insulating layer 212, and may be connected to some of a plurality of upper conductive line patterns 214.

The upper conductive line pattern 214 and the upper conductive via may provide an electrical connection path between the intermediate connection structure 140 and a package connection terminal 230. The upper connection structure 210 may include a redistribution structure and/or a printed circuit board.

The upper insulating layer 212 may include, for example, an inorganic insulating material, an organic insulating material, or a combination thereof. The inorganic insulating material may include, for example, silicon oxide, silicon nitride, or a combination thereof. The organic insulating material may include, for example, polyimide, epoxy resin, or a combination thereof. The upper conductive line pattern 214 and the upper conductive via may include a conductive material including, for example, Cu, Au, Ag, Ni, W, Al, or a combination thereof. In some example embodiments, the upper conductive line pattern 214 and the upper conductive via may further include a barrier material for limiting and/or preventing the conductive material from diffusing to the outside of the upper conductive line pattern 214 and the upper conductive via. The barrier material may include, for example, Ti, Ta, TiN, TaN, or a combination thereof. The upper conductive line pattern 214 may function as a package connection pad of the first semiconductor package P1. The package connection pad of the first semiconductor package P1 may be referred to as a first package connection pad.

The second semiconductor package P2 may include at least one fifth semiconductor chip 310. The second semiconductor package P2 may be electrically connected to the first semiconductor package P1 via a plurality of package connection terminals 230 respectively attached to a plurality of package connection pads of the first semiconductor package P1.

The fifth semiconductor chip 310 may include a semiconductor substrate 312 including a semiconductor device formed on the active surface thereof, and a plurality of chip connection pads 314 arranged on the active surface of the semiconductor substrate 312. The fifth semiconductor chip 310 may include a memory semiconductor chip. The fifth semiconductor chip 310 may include, for example, a DRAM chip, an SRAM chip, a flash memory chip, an EPROM chip, a PRAM chip, an MRAM chip, or an RRAM chip.

Although FIG. 7 illustrates that the fifth semiconductor chip 310 included in the second semiconductor package P2 is mounted on a package base substrate 260 in a flip chip manner, the illustration is an example only, and some example embodiments are not limited thereto. The package-on-package 1000 may include, as the upper package, all types of semiconductor packages which include at least one fifth semiconductor chip 310 and the package connection terminal 230 in a lower region thereof to be electrically connected to the first semiconductor package P1.

The package base substrate 260 may include a base board layer 262 and a plurality of board pads 264 arranged on an upper surface and under a lower surface of the base board layer 262. The plurality of board pads 264 may include a plurality of board upper surface pads 2644 arranged on the upper surface of the base board layer 262 and a plurality of board lower surface pads 2642 arranged under the lower surface of the base board layer 262. In some example embodiments, the package base substrate 260 may include a printed circuit board. For example, the package base substrate 260 may include a multi-layer printed circuit board. The base board layer 262 may include at least one material of phenol resin, epoxy resin, and polyimide.

On the upper surface and under the lower surface of the base board layer 262, a solder resist layer 266 exposing the plurality of board pads 264 may be formed. The solder resist layer 266 may include an upper surface solder resist layer 2664 covering the upper surface of the base board layer 262 and exposing the plurality of board upper surface pads 2644, and a lower surface solder resist layer 2662 covering the lower surface of the base board layer 262 and exposing the plurality of board lower surface pads 2642.

The package base substrate 260 may include a board wiring 268 electrically connecting the plurality of board upper surface pads 2644 to the plurality of board lower surface pads 2642 inside the base board layer 262. The board wiring 268 may include a board wiring line and a board wiring via. The board wiring 268 may include Cu, Ni, stainless steel, or beryllium copper.

The plurality of board upper surface pads 2644 may be electrically connected to the fifth semiconductor chip 310. For example, a plurality of chip connection terminals 320 may be respectively arranged between the plurality of chip connection pads 314 of the fifth semiconductor chip 310 and the plurality of board upper surface pads 2644 of the package base substrate 260, and may electrically connect the fifth semiconductor chip 310 to the package base substrate 260. In some example embodiments, an underfill layer 330 surrounding the plurality of chip connection terminals 320 may be arranged between the fifth semiconductor chip 310 and the package base substrate 260. The underfill layer 330 may include, for example, an epoxy resin formed by using a capillary under-fill method. In an some example embodiments, the underfill layer 330 may include NCF.

An upper molding layer 340 surrounding the fifth semiconductor chip 310 may be arranged on the package base substrate 260. The upper molding layer 340 may include, for example, EMC.

The plurality of board lower surface pads 2642 may function as package connection pads of the second semiconductor package P2. The package connection pad of the second semiconductor package P2 may be referred to as a second package connection pad. The plurality of package connection terminals 230 may be arranged between a plurality of first package connection pads and a plurality of second package connection pads, and may electrically connect the first semiconductor package P1 to the second semiconductor package P2.

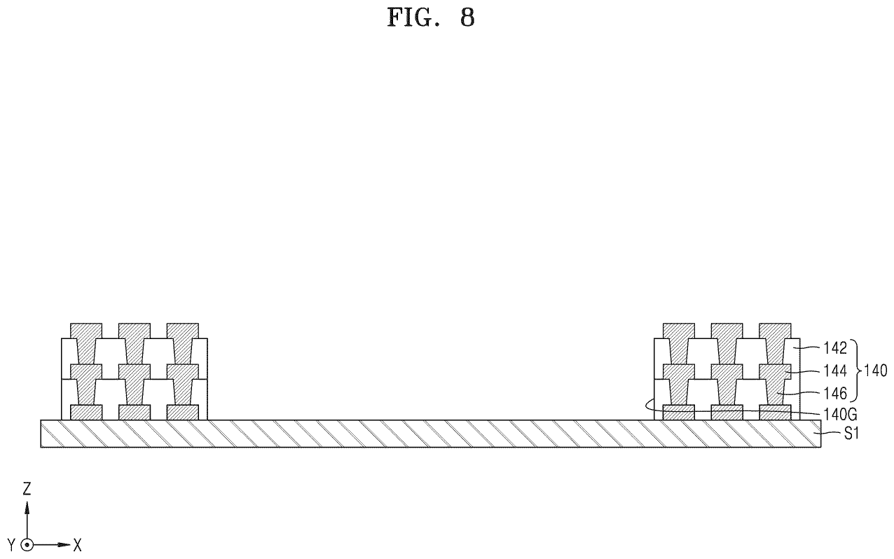

FIGS. 8 through 14 are cross-sectional views describing a method of manufacturing a semiconductor package, according to some example embodiments. FIGS. 8 through 14 are described with reference to FIGS. 1 and 2 together.

Referring to FIG. 8, the mounting space 140G penetrating the intermediate connection structure 140 may be formed in the intermediate connection structure 140. The mounting space 140G of the intermediate connection structure 140 may be formed by using, for example, mechanical drilling, laser drilling, sandblasting, dry etching, and/or wet etching. Next, a first support structure S1 may be attached onto a lower surface of the intermediate connection structure 140. The first support structure S1 may include any material capable of fixing the first support structure S1, such as an adhesive film. The adhesive film may include, for example, a thermosetting adhesive film in which adhesive force is weakened by using heat treatment or an ultraviolet curable adhesive film in which adhesive force is weakened by using ultraviolet irradiation.

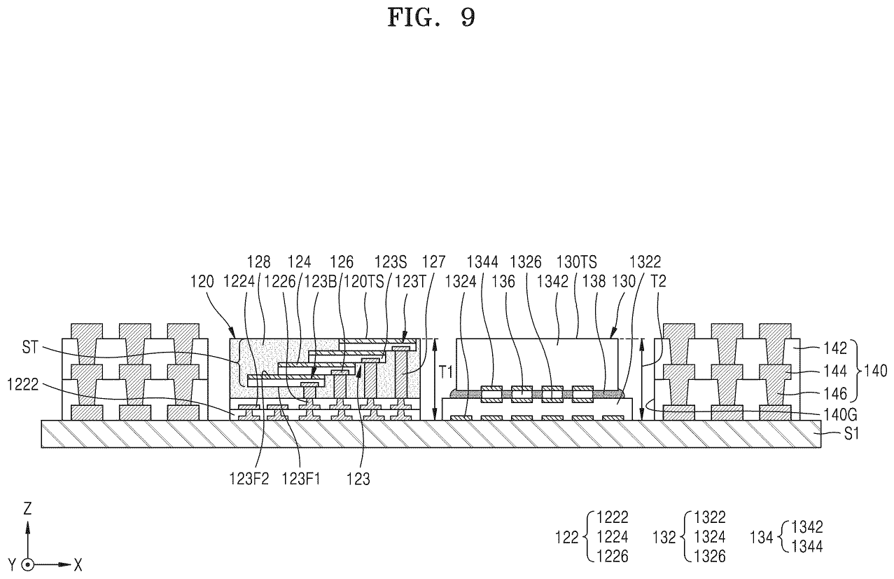

Referring to FIG. 9, the first semiconductor device 120 and the second semiconductor device 130 may be attached onto the first support structure S1. The first semiconductor device 120 may be attached onto the first support structure S1 such that the internal connection structure 122 of the first semiconductor device 120 faces the first support structure S1. The second semiconductor device 130 may be attached onto the first support structure S1 such that the first lower chip pad 1324 of the lower semiconductor chip 132 of the second semiconductor device 130 faces the first support structure S1.

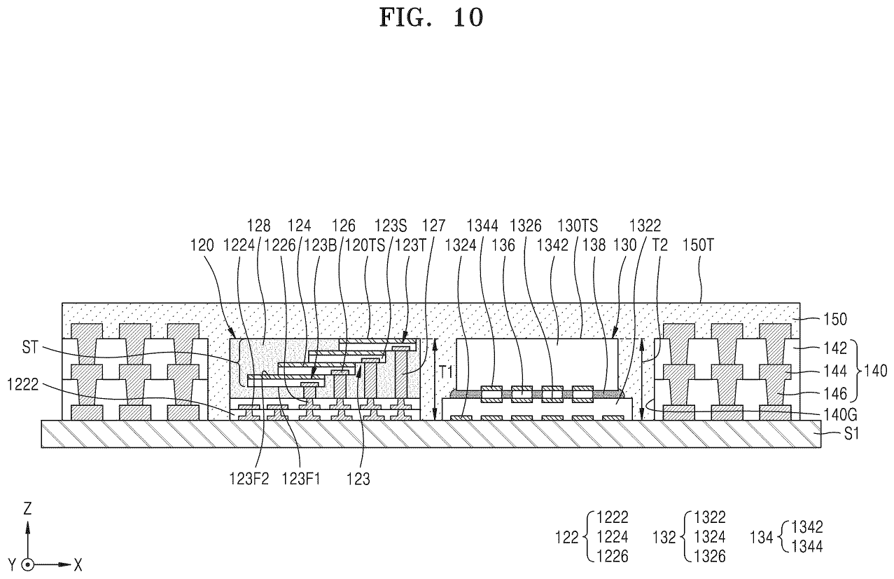

Referring to FIG. 10, the molding layer 150 covering the first semiconductor device 120, the second semiconductor device 130, and the intermediate connection structure 140 may be formed. The molding layer 150 may be formed by using a known method. For example, the molding layer 150 may be formed by laminating a molding material (for example, a build-up film) on the upper surface of each of the first semiconductor device 120, the second semiconductor device 130, and the intermediate connection structure 140. Alternatively, the molding layer 150 may be formed by applying a liquid molding material on the first support structure S1, the first semiconductor device 120, the second semiconductor device 130, and the intermediate connection structure 140, and then curing the molding material.

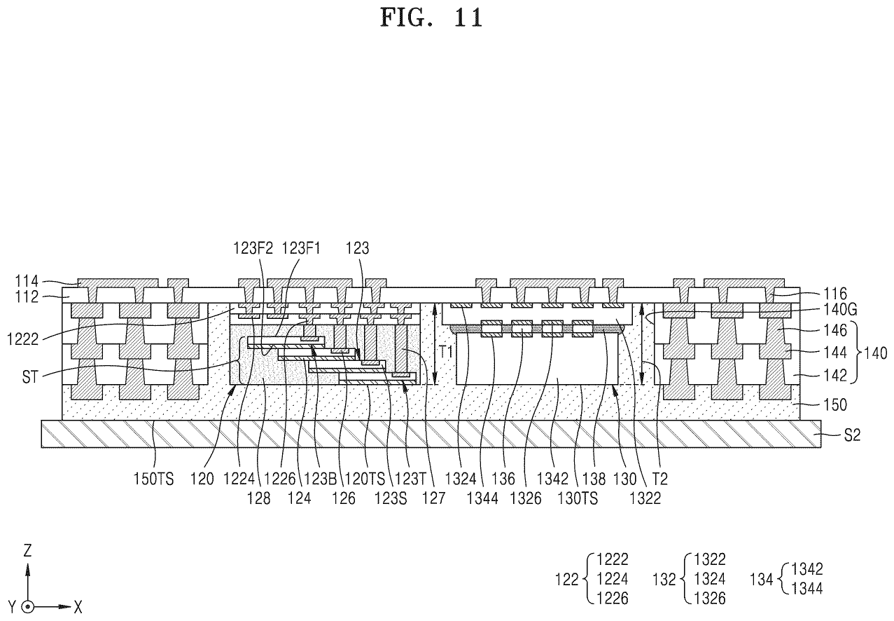

Referring to FIGS. 10 and 11, after the first support structure S1 is removed and the resultant product of FIG. 10 is inverted, a second support structure S2 may be attached onto an upper surface 150TS of the molding layer 150. For example, the first support structure S1 may be removed after the adhesive force of the first support structure S1 is weakened by using heat and/or ultraviolet rays. The second support structure S2 may include a material similar to that of the first support structure S1.

After the second support structure S2 is attached onto the molding layer 150, the lower insulating layer 112, the lower conductive line pattern 114, and the lower conductive via 116 may be formed on the first semiconductor device 120, the second semiconductor device 130, and the intermediate connection structure 140. After the lower insulating layer 112 is first formed, the lower conductive line pattern 114 and the lower conductive via 116 may be formed on the lower insulating layer 112.

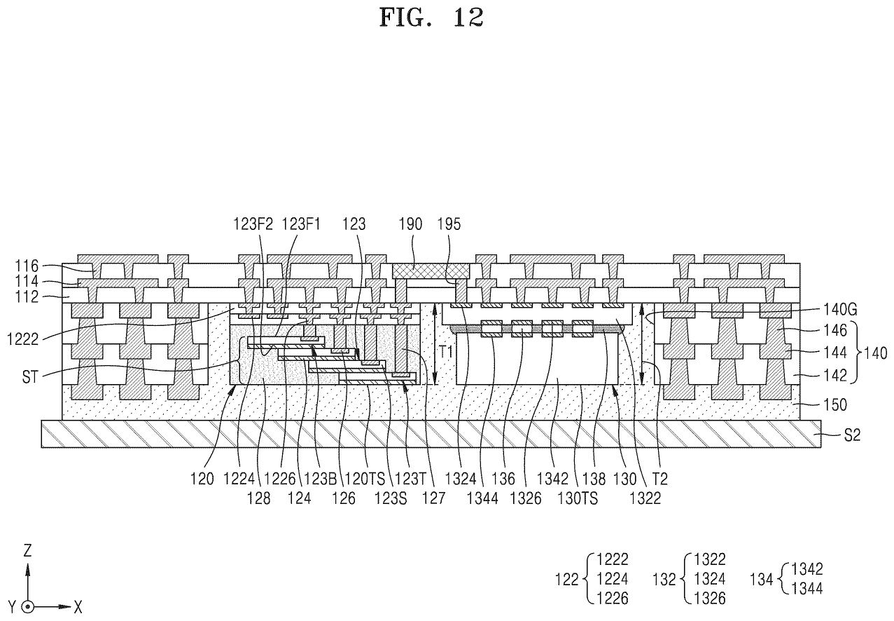

Referring to FIG. 12, the lower insulating layer 112, the lower conductive line pattern 114, and the lower conductive via 116 may be repeatedly formed to provide multilayers. Furthermore, the bridge chip 190 may be mounted inside the lower insulating layer 112. The bridge chip 190 may be electrically connected to the first semiconductor device 120 and/or the second semiconductor device 130 via the bridge connection structure 195. In some example embodiments, the bridge chip 190 may be arranged apart from the uppermost lower insulating layer 112 in the vertical direction (Z direction). In some example embodiments, the bridge chip 190 may be arranged inside the uppermost lower insulating layer 112.

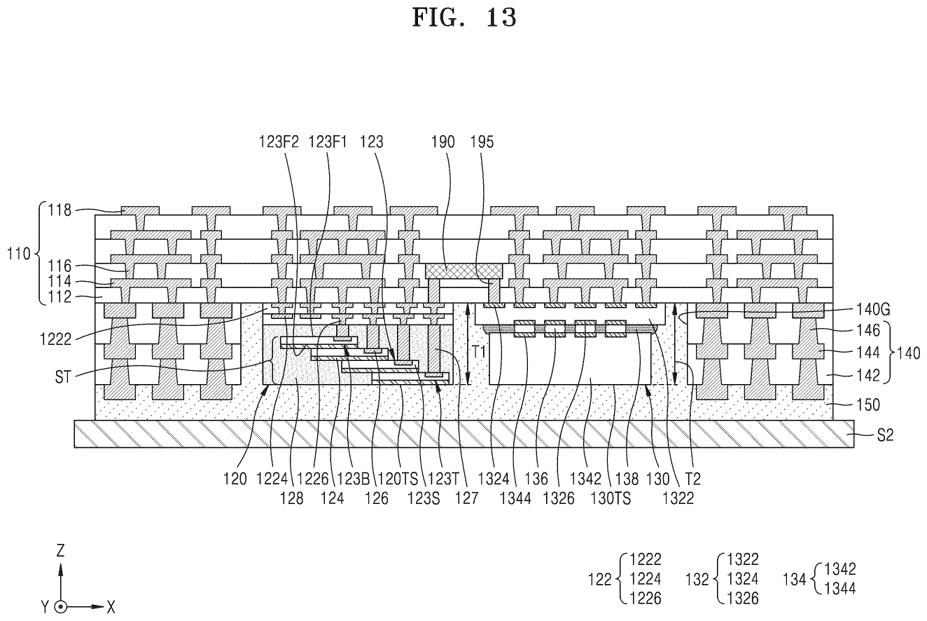

Referring to FIG. 13, the lower insulating layer 112, the lower conductive line pattern 114, and the lower conductive via 116 may be repeatedly formed to provide additional multilayers. The lower pad 118 may be formed on the lowermost lower insulating layer 112 to form the lower connection structure 110.

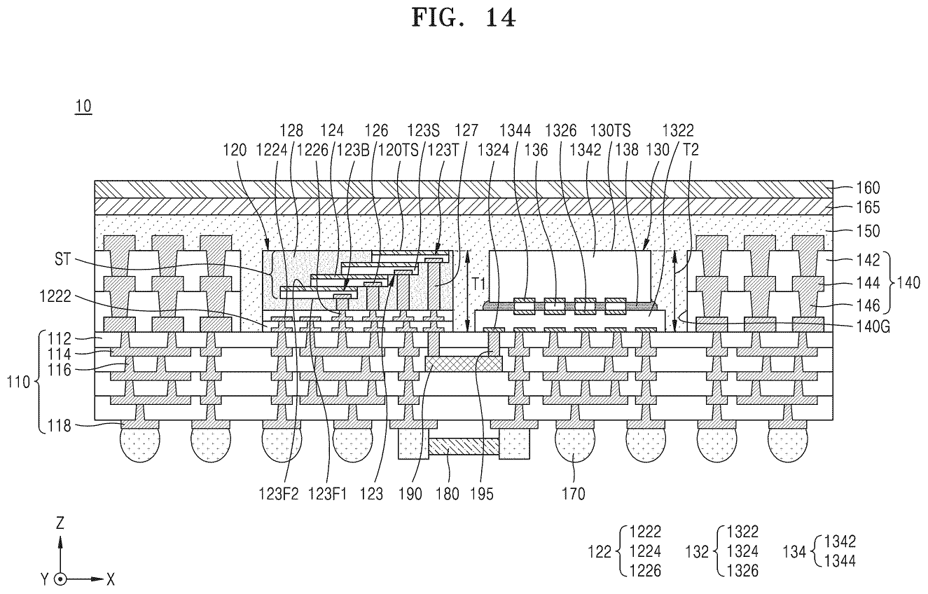

Referring to FIGS. 13 and 14, after the second support structure S2 is removed and the resultant product of FIG. 12 is turned over, the passive component 180 and the external connection terminal 170 may be attached onto the lower pad 118. For example, the second support structure S2 may be removed after the adhesive force of the second support structure S2 is weakened by using heat and/or ultraviolet rays. For example, the passive component 180 may include a capacitor. For example, by reflowing the solder ball, the external connection terminal 170 attached onto the lower pad 118 of the lower connection structure 110 may be formed. Next, by attaching the thermally conductive adhesive layer 165 and the heat dissipation plate 160 onto the molding layer 150, the semiconductor package 10 of FIG. 1 may be manufactured.

FIGS. 8 through 14 illustrate, as examples, that the lower connection structure 110 is formed after the first semiconductor device 120 and the second semiconductor device 130 are mounted in the mounting space 140G. However, in some example embodiments, after the lower connection structure 110 is formed first, the first semiconductor device 120 and the second semiconductor device 130 may be mounted onto the lower connection structure 110. In some example embodiments, the semiconductor package 20 illustrated in FIG. 3 may be manufactured.

While the inventive concepts have been shown and described with reference to some example embodiments thereof, it will be understood that various change in form and details may be made therein without departing from the spirit and scope of the following claims.

What is claimed is:

1. A semiconductor package comprising:
a lower connection structure;
an intermediate connection structure on the lower connection structure, the intermediate connection structure defining a mounting space therethrough;
a first semiconductor device on the lower connection structure, the first semiconductor device being inside the mounting space;
a second semiconductor device on the lower connection structure, the second semiconductor device being inside the mounting space, and the second semiconductor device being apart from the first semiconductor device in a horizontal direction; and
a molding layer on the lower connection structure, the molding layer surrounding the first semiconductor device and the second semiconductor device,
wherein the first semiconductor device comprises
a plurality of semiconductor chips stacked in a vertical direction perpendicular to the horizontal direction, and
vertical connection conductors extending from lower surfaces of the plurality of semiconductor chips in the vertical direction,
wherein the plurality of semiconductor chips are sequentially stacked offset from each other along the horizontal direction.

2. The semiconductor package of claim 1, wherein at least one of the first semiconductor device and the second semiconductor device electrically contacts the lower connection structure.

3. The semiconductor package of claim 1, further comprising connection members between the lower connection structure and at least one of the first semiconductor device and the second semiconductor device.

4. The semiconductor package of claim 1, further comprising a heat dissipation plate on the molding layer.

5. The semiconductor package of claim 1, wherein
an upper surface of the molding layer is at a higher vertical level than each of an upper surface of the first semiconductor device and an upper surface of the second semiconductor device.

6. The semiconductor package of claim 1, wherein
the first semiconductor device has a first thickness that is a vertical distance from an upper surface of the lower connection structure to an upper surface of the first semiconductor device,
the second semiconductor device has a second thickness that is a vertical distance from the upper surface of the lower connection structure to an upper surface of the second semiconductor device, and
the first thickness and the second thickness are a same thickness.

7. The semiconductor package of claim 1, further comprising a passive component under a lower surface of the lower connection structure.

8. A semiconductor package comprising:
a lower connection structure including
a lower insulating layer,
a plurality of lower conductive line patterns on at least one of an upper surface and a lower surface of the lower insulating layer, and
a plurality of lower conductive vias penetrating the lower insulating layer, the plurality of lower conductive vias being respectively connected to some of the plurality of lower conductive line patterns;
an intermediate connection structure on the lower connection structure, the intermediate connection structure defining a mounting space therethrough;
a first semiconductor device on the lower connection structure, the first semiconductor device being inside the mounting space;
a second semiconductor device on the lower connection structure, the second semiconductor device being inside the mounting space, and the second semiconductor device being apart from the first semiconductor device in a horizontal direction;
a molding layer on the lower connection structure, the molding layer surrounding the first semiconductor device and the second semiconductor device; and
a bridge chip inside the lower connection structure, the bridge chip configured to electrically connect the first semiconductor device to the second semiconductor device,
wherein the first semiconductor device comprises
a plurality of semiconductor chips stacked in a vertical direction perpendicular to the horizontal direction, the plurality of semiconductor chips including chip pads therein, and
vertical connection conductors extending from the chip pads of the plurality of semiconductor chips in the vertical direction,
wherein the plurality of semiconductor chips are sequentially stacked offset from each other along the horizontal direction.

9. The semiconductor package of claim 8, wherein the plurality of lower conductive vias have a tapered shape having width along the horizontal direction that increases away from the first semiconductor device in the vertical direction.

10. The semiconductor package of claim 8, wherein the plurality of lower conductive vias have a tapered shape having width along the horizontal direction that decreases away from the first semiconductor device in the vertical direction.

11. The semiconductor package of claim 8, further comprising a heat dissipation plate on the molding layer,
wherein the heat dissipation plate covers an entire upper surface of the molding layer.

12. The semiconductor package of claim 8, wherein the first semiconductor device further comprises an additional insulating layer between the plurality of semiconductor chips.

13. The semiconductor package of claim 12, wherein the additional insulating layer and the first semiconductor device have a same footprint.

14. The semiconductor package of claim 8, wherein
an upper surface of the molding layer and each of an upper surface of the first semiconductor device and an upper surface of the second semiconductor device are at a same vertical level.

15. The semiconductor package of claim 8, wherein the bridge chip is apart from an uppermost end of the lower insulating layer along the vertical direction.

16. The semiconductor package of claim 8, wherein the intermediate connection structure comprises a conductive post.

17. A semiconductor package comprising:
a lower connection structure including
a lower insulating layer,
a plurality of lower conductive line patterns on at least one of an upper surface and a lower surface of the lower insulating layer, and
a plurality of lower conductive vias penetrating the lower insulating layer, the plurality of lower conductive vias being respectively connected to some of the plurality of lower conductive line patterns;
an intermediate connection structure on the lower connection structure, the intermediate connection structure defining a mounting space therethrough, the intermediate connection structure including
an intermediate insulating layer,
a plurality of intermediate conductive line patterns on at least one of an upper surface and a lower surface of the intermediate insulating layer, and
a plurality of intermediate conductive vias penetrating the intermediate insulating layer, the plurality of intermediate conductive vias being respectively connected to some of the plurality of intermediate conductive line patterns;
a first semiconductor device on the lower connection structure, the first semiconductor device being inside the mounting space;
a second semiconductor device on the lower connection structure, the second semiconductor device being inside the mounting space, and the second semiconductor device being apart from the first semiconductor device in a horizontal direction;
a molding layer on the lower connection structure, the molding layer surrounding the first semiconductor device and the second semiconductor device; and
a bridge chip inside the lower connection structure, the bridge chip configured to electrically connect the first semiconductor device to the second semiconductor device,
wherein the first semiconductor device comprises
an internal connection structure,
a plurality of semiconductor chips on the internal connection structure, the plurality of semiconductor chips being stacked in a vertical direction perpendicular to the horizontal direction, and the plurality of semiconductor chips including chip pads therein,
vertical connection conductors extending from the chip pads of the plurality of semiconductor chips in the vertical direction, and
an encapsulation material surrounding the plurality of semiconductor chips and the vertical connection conductors,
wherein the plurality of semiconductor chips are sequentially stacked offset from each other along the horizontal direction.

18. The semiconductor package of claim 17, further comprising a heat dissipation plate arranged on the molding layer,
wherein, in a plan view, the heat dissipation plate has a symmetric shape.

19. The semiconductor package of claim 17, wherein the second semiconductor device comprises a lower semiconductor chip, and an upper semiconductor chip on the lower semiconductor chip.

20. The semiconductor package of claim 17, wherein the first semiconductor device comprises a memory chip.
